(19) United States
(12) Patent Application Publication
(10) Pub. No.: US 2025/0285832 A1
(43) Pub. Date: Sep. 11, 2025

(54) Ion Milling Device, Holder, and Cross-Section Milling Treatment Method

(71) Applicant: Hitachi High-Tech Corporation, Minato-ku, Tokyo (JP)

(72) Inventors: Saki FUKUSHIMA, Tokyo (JP); Masanari FURIKI, Tokyo (JP); Hisayuki TAKASU, Tokyo (JP)

(21) Appl. No.: 18/860,101

(22) PCT Filed: Jun. 13, 2022
(86) PCT No.: PCT/JP2022/023644

§ 371 Date: Oct. 25, 2024

(51) Int. Cl. H01J 37/20; H01J 37/305

(52) U.S. Cl. CPC H01J 37/20; H01J 37/3053; H01J 2237/202

(57) ABSTRACT

Provided is an ion milling device including a mask and sample stage unit 113 including a holder 111 to which a sample 112 adheres, a sample unit base 106 on which the mask and sample stage unit is mounted, and an ion source 103 that emits an unfocused ion beam 104 to the sample, in which the holder has a first surface to a third surface, a first surface 201 and a second surface 203 to which the sample adheres are connected by a third surface 202, an angle formed between the first surface and the third surface is a right angle, an angle formed between the first surface and the second surface is an acute angle, and when the mask and sample stage unit is mounted on the sample unit base such that the mask and sample stage unit faces the ion source, the first surface of the holder is perpendicular to an ion beam center of the ion beam.

### TECHNICAL FIELD

The present invention relates to an ion milling device, a holder, and a cross-section milling treatment method.

### BACKGROUND ART

An ion milling device for emitting an unfocused ion beam and exposing a cross-section to observe an internal structure of a sample has been known. PTL 1 discloses an ion milling device for performing cross-section milling in which a mask (shielding plate) disposed above a sample shields a part of an ion beam to expose a cross-section of the sample along an end surface of the mask. Further, in the ion milling device according to PTL 1, it is possible to slide a sample mask unit to form a cross-section having a width equal to or larger than an ion beam width or perform processing at a plurality of points.

On the other hand, a FIB-SEM for processing a sample by a focused ion beam (FIB) and performing observation and measurement by a scanning electron microscope has been known. PTL 2 discloses that an inclined cross-section of a sample including a circuit element is exposed by irradiation with a focused ion beam, and measurement of a pattern in a depth direction is performed.

### CITATION LIST

### Patent Literature

PTL 1: WO2017/145371

PTL 2: WO2016/002341

### SUMMARY OF INVENTION

### Technical Problem

When an inclined cross-section of a sample is exposed, it is difficult to obtain an inclined cross-section with a cut edge at a desired angle by controlling an inclination angle in the ion milling device according to PTL 1. On the other hand, in the focused ion beam device according to PTL 2, the processing of the inclined cross-section can be implemented only in a narrow region having a width and a depth of about several hundred micrometers.

An object of the invention is to provide an ion milling device capable of producing an inclined cross-section, which is precisely controlled over a wide area, of a laminated structure called a coating film or a functional thin film or a three-dimensional device such as MEMS.

### Solution to Problem

An ion milling device according to an embodiment of the invention includes a mask and sample stage unit including a holder to which a sample adheres, a sample unit base on which the mask and sample stage unit is mounted, and an ion source configured to emit an unfocused ion beam to the sample. The holder has a first surface to a third surface, the first surface and the second surface to which the sample adheres are connected to each other by the third surface, an angle formed between the first surface and the third surface is a right angle, and an angle formed between the first surface and the second surface is an acute angle. When the mask and sample stage unit is mounted on the sample unit base such that the mask and sample stage unit faces the ion source, the first surface of the holder is perpendicular to an ion beam center of the ion beam.

### Advantageous Effects of Invention

Provided is an ion milling device capable of producing an inclined cross-section precisely controlled. Other objects and novel features will become apparent from the description of this description and the accompanying drawings.

### BRIEF DESCRIPTION OF DRAWINGS

FIG. 1 is a diagram showing a configuration example of an ion milling device.

FIG. 2A is a bird's-eye view of a holder.

FIG. 2B is a top view of the holder.

FIG. 2C is a side view of the holder.

FIG. 3 is an operation flow of performing a cross-section milling treatment for producing an inclined cross-section of a sample.

FIG. 4 is a diagram illustrating a method for adjusting a protrusion amount of a sample using an adjustment stage.

FIG. 5A is a diagram illustrating a method for adjusting an irradiation position of an ion beam.

FIG. 5B is a diagram illustrating the method for adjusting the irradiation position of the ion beam.

FIG. 6A is a diagram showing states of the holder and the sample after the cross-section milling treatment is completed.

FIG. 6B is a diagram showing the states of the holder and the sample after the cross-section milling treatment is completed.

FIG. 6C is a schematic view of a sample cross-section.

FIG. 7A shows an example of a holder having a sample placement surface with a small inclination angle.

FIG. 7B shows an example of a holder having a sample placement surface with a large inclination angle.

FIG. 8 shows an example in which a mask and sample stage unit is mounted on a sample unit base 106 via a slide movement mechanism.

### DESCRIPTION OF EMBODIMENTS

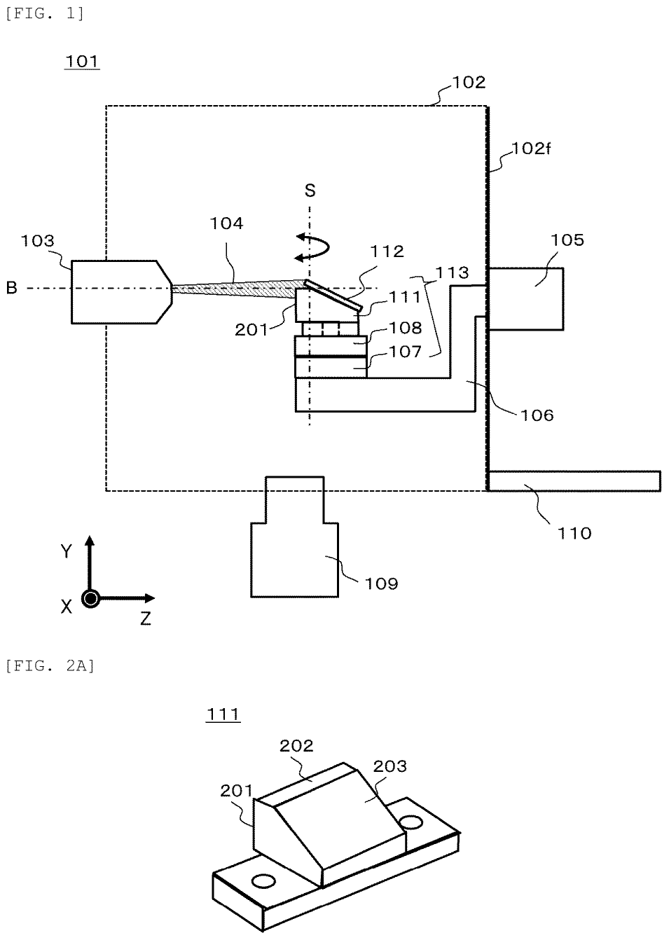

FIG. 1 shows a configuration example of an ion milling device 101. The ion milling device 101 includes, as main components, a vacuum chamber 102, an ion source 103 attached to the vacuum chamber 102, a sample stage 105 attached to a surface of the vacuum chamber 102, which is different from the surface to which the ion source 103 is attached, a sample unit base 106 extending from the sample stage 105, a mask and sample stage unit 113 which is placed on the sample unit base 106 and on which a sample 112 to be subjected to a cross-section milling treatment is placed, a vacuum exhaust system 109 exhausting an inside of the vacuum chamber 102, and a linear guide 110 provided on the surface of the vacuum chamber 102 to which the sample stage 105 is attached.

The sample stage 105 is attached to a flange 102f that also serves as a part of a container wall of the vacuum chamber 102, and the vacuum chamber 102 can be opened to the atmosphere by pulling out the flange 102f along the linear guide 110. At this time, the sample stage 105 is pulled out to the outside of the vacuum chamber 102 together with the sample unit base 106. In this way, a sample stage extracting mechanism is configured.

The mask and sample stage unit 113 is assembled by stacking a micro-movement mechanism 107, a coupling member 108, and a holder 111 in this order, and the sample 112 is adhesively fixed onto the holder 111. The holder 111 is an integrated mask and sample stage holder having a function as a sample stage on which the sample 112 is placed and a function as a mask for masking the sample 112. The mask and sample stage unit 113 swings around a swing axis S perpendicular to a center (ion beam center) B of the ion beam 104 by a drive source provided in the sample stage 105. In FIG. 1, an ion beam center B is parallel to a Z-axis, the swing axis S is parallel to a Y-axis, the ion source 103 and the mask and sample stage unit 113 face each other, and a boundary (edge) between the holder 111 and the sample 112 is parallel to an X-axis. By the swing operation, the mask and sample stage unit 113 is rotationally driven in a range in which an angle formed between the edge and the X-axis direction is ±θ.

The micro-movement mechanism 107 constituting the mask and sample stage unit 113 is configured to be movable in a plane perpendicular to the ion beam center B, that is, in two axes including an X-axis direction and a Y-axis direction in the state shown in FIG. 1, and is used to adjust a relative position between the ion beam center B and the mask and sample stage unit 113. Details of the adjustment will be described below. The coupling member 108 serves as a base for placing the holder 111 on the micro-movement mechanism 107.

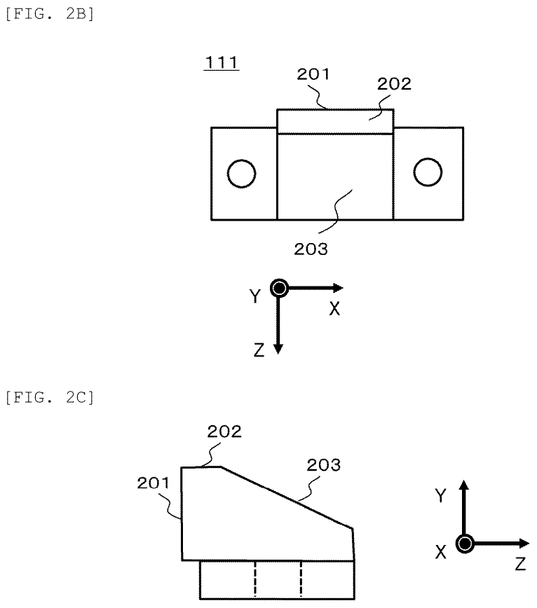

FIGS. 2A to 2C show a shape of the holder 111. FIG. 2A is a bird's-eye view, FIG. 2B is a top view, and FIG. 2C is a side view. In FIGS. 2B and 2C, coordinate axes corresponding to the coordinate axes in FIG. 1 are displayed. The holder 111 includes a mask surface (first surface) 201 facing the ion source 103 and a sample placement surface (second surface) 203 to which the sample 112 is adhesively fixed when the mask and sample stage unit 113 faces the ion source 103, and the mask surface 201 and the sample placement surface 203 are connected by a sample protection surface (third surface) 202. The sample protection surface 202 is provided so that a portion of the sample 112 except for a target processing position (a position where a cross-section is desired to be exposed) is not scraped by the irradiation with an ion beam. In order to reduce the amount of the holder 111 scraped by the irradiation with the ion beam, a material of the holder 111 is preferably titanium, graphite carbon, or the like having high ion beam resistance.

The mask surface 201 is a plane parallel to an XY plane, the sample protection surface 202 is a plane parallel to an XZ plane, and therefore, an angle between the mask surface 201 and the sample protection surface 202 is a right angle. The sample placement surface 203 is inclined in the Z direction, and an angle formed between the mask surface 201 and the sample placement surface 203 is an acute angle. An intersection line between the mask surface 201 and the sample protection surface 202 is parallel to an intersection line between the sample protection surface 202 and the sample placement surface 203.

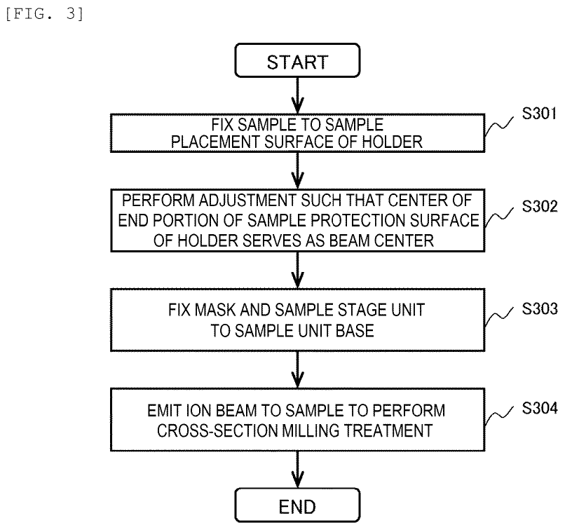

A procedure for producing the inclined cross-section of the sample 112 placed on the mask and sample stage unit 113 by the ion milling device 101 will be described with reference to FIG. 3.

S301: The user adhesively fixes the sample 112 to the sample placement surface 203 of the holder 111. As shown in FIG. 1, a portion of the sample 112 protruding from the intersection line between the sample protection surface 202 and the sample placement surface 203 of the holder 111 is a portion to be cross-section milled by the ion beam 104. Therefore, when the sample 112 is fixed to the holder 111, the protrusion amount is adjusted using an adjustment stage 205 so that the target processing position of the sample 112 is positioned on the intersection line between the sample protection surface 202 and the sample placement surface 203. FIG. 4 shows a state in which the protrusion amount of the sample 112 is adjusted by placing the holder 111 on the adjustment stage 205.

The adjustment stage 205 is a stage for adjusting the protrusion amount of the sample 112, which is produced in accordance with the holder 111. The adjustment stage 205 is provided with a triangular groove on which the holder 111 is mounted. The adjustment of the protrusion amount is performed in a state where the holder 111 is placed on the adjustment stage 205 such that a bottom surface of the holder 111 comes into contact with a placement surface 206 which is one side surface of the triangular groove, and the mask surface 201 of the holder 111 comes into contact with an adjustment surface 207 which is the other side surface of the triangular groove.

In order to precisely adjust the protrusion amount, the adjustment stage 205 is provided with a protrusion amount adjustment jig 204. The triangular groove is formed at an inclination such that when the sample 112 is placed on the sample placement surface 203 of the holder 111, the sample 112 slides down toward the sample protection surface 202 by its own weight. The sample 112 is held on the sample placement surface 203 by the protrusion amount adjustment jig 204, and the sample protrusion amount can be set by sliding a protrusion amount adjustment bar 208 in arrow directions. The protrusion amount of the sample can be precisely adjusted by using a precise screw mechanism used for a micrometer for the protrusion amount adjustment bar 208. When the desired protrusion amount is reached, the sample 112 is adhesively fixed to the sample placement surface 203.

The protrusion amount is set based on a distance from a distal end of the trimmed sample 112 to the target processing position when the sample 112 is trimmed. When the target processing position is not specified and processing is to be performed at any location, it is preferable to set the protrusion amount to about 50 μm. For fixing the sample 112 to the sample placement surface 203, an adhesive such as a carbon paste, hot wax, or manicure can be used. When the sample 112 is fixed, the holder 111 is removed from the adjustment stage 205 and attached to the micro-movement mechanism 107 via the coupling member 108.

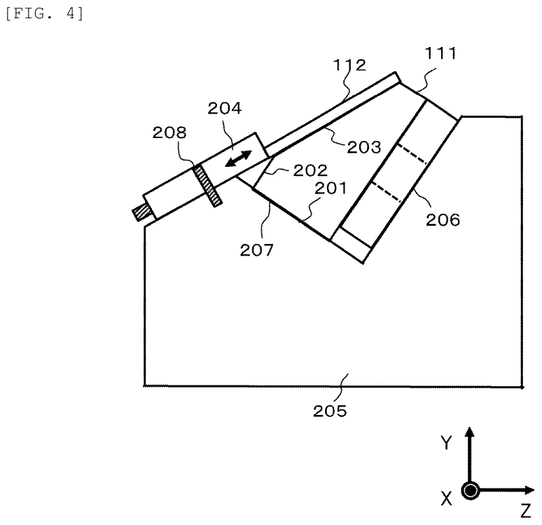

S302: The ion beam center B of the ion beam 104 emitted from the ion source 103 is adjusted to be positioned at a center of an end portion of the sample protection surface 202 of the holder 111. An example of the adjustment method will be described with reference to FIGS. 5A and 5B.

Since the relative position between the ion beam center B and the mask and sample stage unit 113 needs to be precisely adjusted, the adjustment is performed using an optical microscope. The optical microscope includes a fixing stage for reproducibly positioning the mask and sample stage unit 113 at a fixed position on an observation stage of the optical microscope. Prior to the adjustment in step S302, the field of view of the optical microscope is adjusted so that the ion beam center B is positioned at a center of the field of view of the optical microscope. This adjustment is performed at a timing of maintenance, and does not need to be performed every time the sample is placed on the holder.

The adjustment of the field of view of the optical microscope will be described with reference to FIG. 5A. The micro-movement mechanism 107 is set at a standard position (X-axis direction=0, Y-axis direction=0), photosensitive paper, silver foil, or the like is attached to the mask surface 201 of the holder 111, and the field of view of the optical microscope is moved so that a mark formed by emitting the ion beam 104, that is, an ion beam center 502 is positioned at a center of a field of view 501 of the optical microscope.

FIG. 5B shows a field of view 503 of the optical microscope when the mask and sample stage unit 113 on which the sample 112 is placed is disposed on the fixing stage of the optical microscope in step S302. When the micro-movement mechanism 107 is at the standard position (X-axis direction=0, Y-axis direction=0), an image of the sample 112 is a sample image 112I₁, and an image of the mask surface 201 is a mask surface image 201I₁. Since the ion beam center is the center of the field of view 503, a position X3 in the X-axis direction and a position Y3 in the Y-axis direction of the micro-movement mechanism 107 may be adjusted so that the center of the end portion of the sample protection surface 202 of the holder 111 is positioned at the center of the field of view 503 according to the target processing position. Accordingly, the sample protection surface 202 of the holder is adjusted to be positioned along the ion beam center of the ion beam. An image of the sample 112 after adjustment by the micro-movement mechanism 107 is a sample image 112I₂, and an image of the mask surface 201 is a mask surface image 201I₂.

S303: The mask and sample stage unit 113 is attached to the sample unit base 106. The attaching position of the sample unit base 106 to the mask and sample stage unit is fixed. As shown in FIG. 1, the mask surface 201 of the holder 111 is fixed facing the ion source 103.

S304: The ion beam 104 is emitted to the sample 112 to perform a cross-section milling treatment. When the irradiation direction of the ion beam 104 is concentrated in one direction, a processing mark appears in the cross-section of the sample. In order to prevent the occurrence of such disturbance of the cross-section, swing processing in which milling treatment is performed while swinging the mask and sample stage unit 113 around the swing axis S is performed.

As described above, a protruding region of the sample 112 adhesively fixed to the sample placement surface 203 is milled by irradiation with the ion beam.

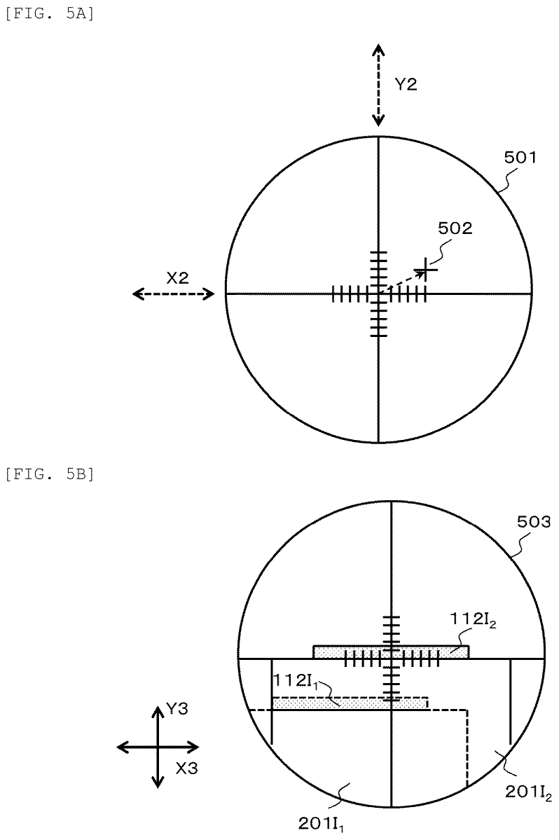

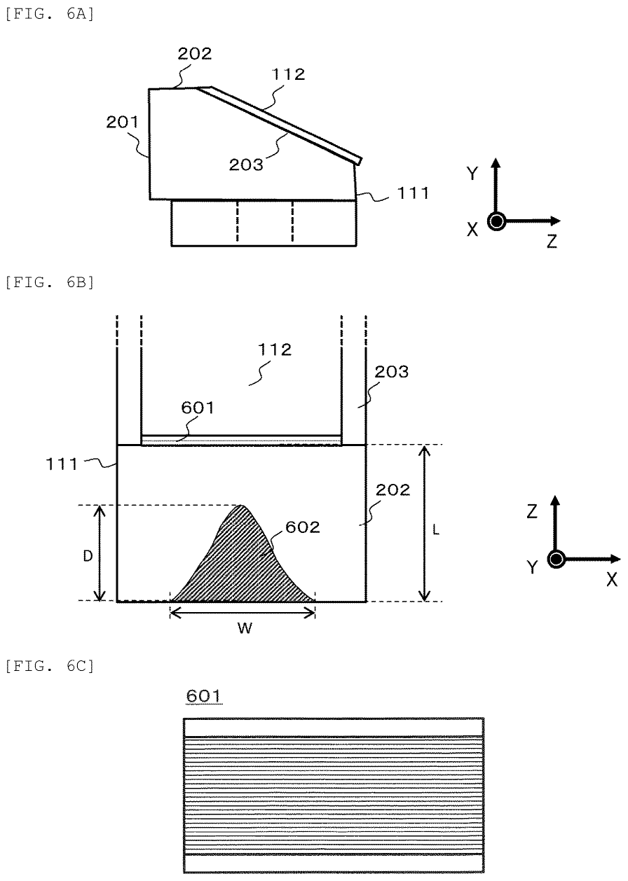

FIGS. 6A to 6C show states of the holder 111 and the sample 112 after the cross-section milling treatment is completed. As shown in FIG. 6A, a cross-section 601 of the sample 112 is exposed along the sample protection surface 202 of the holder 111. The cross-section 601 is an inclined cross-section in which a cut edge is inclined in accordance with the inclination of the sample placement surface 203 of the holder 111.

As shown in FIG. 1, since the ion beam 104 is adjusted to be emitted such that the ion beam center B moves along the sample protection surface 202 during the milling treatment, the sample protection surface 202 of the holder 111 is also scraped together with the sample 112 by the irradiation with the ion beam 104. This state is shown in FIG. 6B. At this time, regarding a milling region 602 of the sample protection surface 202, a length cut in an extension direction (Z-axis direction) of the ion beam center B is defined as a processing depth D, and a length of the milling region 602 on the end portion of the sample protection surface 202 is defined as a processing width W.

A length L of the sample protection surface 202 in the Z-axis direction affects the accuracy of milling. When the length L is too small, for example, L<0.1 mm, the milling region 602 reaches the sample placement surface 203 before completion of processing, and a cross-section along the sample protection surface 202 cannot be obtained. In contrast, when the length L is too large, for example, L>10 mm, a position of the sample 112 relative to the ion source 103 becomes farther, and thus the intensity of the ion beam 104 which is unfocused decreases. Accordingly, the processing rate decreases. When the processing time is extended due to the decrease in the processing rate, the influence of heating due to sputtering caused by the ion beam 104 on the sample 112 and the holder 111 is remarkable. Specifically, when a thermal expansion coefficient of the sample 112 is different from a thermal expansion coefficient of the holder 111, the degree of adhesion between the holder 111 and the sample 112 decreases during the milling, and the problem that the sputtered particles enter the gap occurs. As a result, the processing accuracy decreases, that is, the cross-section 601 is curved. In order to avoid such a problem, the length L of the sample protection surface 202 in the Z-axis direction is 0.1 mm or more and 10 mm or less, preferably 0.5 mm or more and 3 mm or less, and particularly preferably 2 mm or less.

FIG. 6C schematically shows a state of a cross-section 601 of the obtained sample 112 observed with a scanning electron microscope. The sample 112 has a structure in which a semi-conductor layer and an insulating film layer are laminated on a semi-conductor substrate. When the cross-section 601 is obtained as a flat surface without being curved, a boundary between parallel laminated films without distortion can be observed.

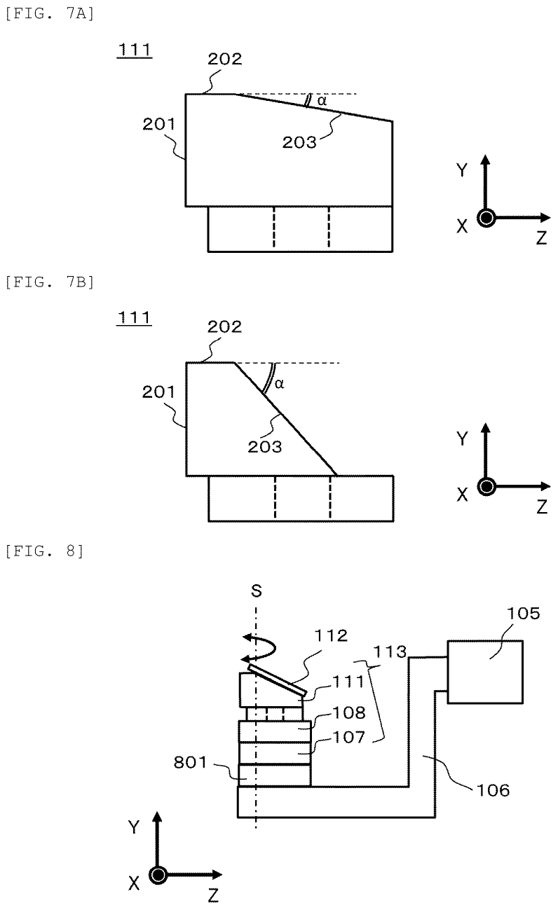

An inclination angle α of the sample placement surface 203 of the holder 111 can be changed by replacing the holder 111 in accordance with the sample 112 to be placed, and can be customized in a range of several degrees to 70 degrees or less. FIG. 7A shows the holder 111 with the inclination angle α=10°, and FIG. 7B shows the holder 111 with the inclination angle α=70°. Only the inclination angle α is changed, and the other sizes are the same. The holder 111 having the optimum inclination angle α can be produced in accordance with the type of the sample 112 to be placed and the observation/measurement purpose.

FIG. 8 shows an example in which the mask and sample stage unit 113 is mounted on the sample unit base 106 via a slide movement mechanism 801. The slide movement mechanism 801 is a mechanism for implementing a wide-area milling treatment or a multi-point milling treatment. The slide movement mechanism 801 includes a drive source and reciprocates the mask and sample stage unit 113 in a direction of the intersection line between the sample protection surface 202 and the sample placement surface 203 of the holder 111, here, in the X-axis direction. The wide-area milling treatment is a treatment of processing a region having a width larger than a width of the ion beam 104, and the multi-point milling treatment is a treatment of processing a plurality of target processing positions of the sample.

When the wide-area milling treatment is performed, the milling treatment may be performed while performing both the reciprocating operation by the slide movement mechanism 801 and the swing operation around the swing axis S. When performing the multi-point milling treatment, the milling treatment may be performed at a plurality of target processing positions by moving the irradiation position of the ion beam 104 by the slide movement mechanism 801.

The invention is not limited to the embodiments described above, and includes various modifications. For example, the above-described embodiments have been described in detail to facilitate understanding of the invention, and the invention is not necessarily limited to those including all the configurations described. A part of a configuration of a certain embodiment can be replaced with a configuration of another embodiment, and a configuration of another embodiment can be added to a configuration of a certain embodiment. A part of a configuration according to each embodiment may be added to, deleted from, or replaced with another configuration.

### REFERENCE SIGNS LIST

101: ion milling device
102: vacuum chamber
102f: flange
103: ion source
104: ion beam
105: sample stage
106: sample unit base
107: micro-movement mechanism
108: coupling member
109: vacuum exhaust system
110: linear guide
111: holder
112: sample
113: mask and sample stage unit
201: mask surface
202: sample protection surface
203: sample placement surface
204: protrusion amount adjustment jig
205: adjustment stage
206: placement surface
207: adjustment surface
208: protrusion amount adjustment bar
501, 503: field of view
502: ion beam center
601: cross-section
602: milling region
801: slide movement mechanism

1. An ion milling device comprising:
a mask and sample stage unit including a holder to which a sample adheres;
a sample unit base on which the mask and sample stage unit is mounted; and
an ion source configured to emit an unfocused ion beam to the sample, wherein
the holder has a first surface to a third surface, the first surface and the second surface to which the sample adheres are connected to each other by the third surface, an angle formed between the first surface and the third surface is a right angle, an angle formed between the first surface and the second surface is an acute angle, and
when the mask and sample stage unit is mounted on the sample unit base such that the mask and sample stage unit faces the ion source, the first surface of the holder is perpendicular to an ion beam center of the ion beam.

2. The ion milling device according to claim 1, wherein
the sample adheres to the second surface such that a protrusion amount from an intersection line between the second surface and the third surface of the holder reaches a predetermined protrusion amount.

3. The ion milling device according to claim 1, wherein
a distance between an intersection line between the first surface and the third surface of the holder and an intersection line between the second surface and the third surface is 0.1 mm or more and 10 mm or less.

4. The ion milling device according to claim 1, wherein
the mask and sample stage unit includes a micro-movement mechanism,
the micro-movement mechanism is configured to move the sample unit base in a plane perpendicular to the ion beam center of the ion beam in a state where the mask and sample stage unit faces the ion source, and
the micro-movement mechanism is adjusted to allow the third surface of the holder to be positioned along the ion beam center of the ion beam.

5. The ion milling device according to claim 1, further comprising:
a sample stage configured to rotationally drive the mask and sample stage unit via the sample unit base, wherein
the sample stage swings the mask and sample stage unit around a swing axis perpendicular to the ion beam center of the ion beam and an intersection line between the second surface and the third surface of the holder.

6. The ion milling device according to claim 5, wherein
the mask and sample stage unit is mounted on the sample unit base via a slide movement mechanism, and
the slide movement mechanism reciprocates the mask and sample stage unit in a direction of the intersection line between the second surface and the third surface of the holder.

7. A holder to which a sample to be cross-section milled by an unfocused ion beam adheres, the holder comprising:
a first surface to a third surface, wherein
the first surface and the second surface to which the sample adheres are connected to each other by the third surface, an angle formed between the first surface and the third surface is a right angle, an angle formed between the first surface and the second surface is an acute angle, and
the ion beam is emitted to the sample from a direction of the first surface.

8. The holder according to claim 7, wherein
the sample adheres to the second surface to reach a predetermined protrusion amount from an intersection line between the second surface and the third surface of the holder.

9. The holder according to claim 7, wherein
a distance between an intersection line between the first surface and the third surface and an intersection line between the second surface and the third surface is 0.1 mm or more and 10 mm or less.

10. The holder according to claim 7, wherein
a material of the holder is titanium or graphite carbon.

11. A cross-section milling treatment method using an ion milling device including a mask and sample stage unit including a holder, a sample unit base on which the mask and sample stage unit is mounted, and an ion source, wherein
the holder has a first surface to a third surface, the first surface and the second surface are connected to each other by the third surface, an angle formed between the first surface and the third surface is a right angle, an angle formed between the first surface and the second surface is an acute angle,
a sample adheres to the second surface of the holder such that a protrusion amount from an intersection line between the second surface and the third surface of the holder reaches a predetermined protrusion amount, and
an unfocused ion beam is emitted from the ion source to the sample from a direction of the first surface of the holder.

12. The cross-section milling treatment method according to claim 11, wherein
the mask and sample stage unit further includes a micro-movement mechanism,
the micro-movement mechanism is configured to move the sample unit base in a plane perpendicular to an ion beam center of the ion beam in a state where the mask and sample stage unit faces the ion source, and
the micro-movement mechanism is adjusted to allow the third surface of the holder to be positioned along the ion beam center of the ion beam.

13. The cross-section milling treatment method according to claim 11, wherein
the ion milling device further includes a sample stage configured to rotationally drive the mask and sample stage unit via the sample unit base, and
the sample stage swings the mask and sample stage unit around a swing axis perpendicular to an ion beam center of the ion beam and an intersection line between the second surface and the third surface of the holder during a period in which the ion source emits the ion beam to the sample.

14. The cross-section milling treatment method according to claim 13, wherein
the mask and sample stage unit is mounted on the sample unit base via a slide movement mechanism, and
the slide movement mechanism reciprocates the mask and sample stage unit in a direction of the intersection line between the second surface and the third surface of the holder during the period in which the ion source emits the ion beam to the sample.

15. The cross-section milling treatment method according to claim 14, wherein
a region of the sample having a width wider than a width of the ion beam is processed or a plurality of target processing positions of the sample are processed.
